(19) United States
(12) Patent Application Publication
(10) Pub. No.: US 2007/0010066 A1
(43) Pub. Date: Jan. 11, 2007

(54) METHOD FOR MANUFACTURING SEMICONDUCTOR DEVICE

(75) Inventor: Koji Takaya, Tokyo (JP)

Correspondence Address: GLOBAL IP COUNSELORS, LLP, 1233 20TH STREET, NW, SUITE 700, WASHINGTON, DC, 20036-2680, US

(73) Assignee: OKI ELECTRIC INDUSTRY CO., LTD., Tokyo (JP)

(21) Appl. No.: 11/425,708

(22) Filed: Jun. 22, 2006

(30) Foreign Application Priority Data
Jul. 7, 2005 (JP) 2005-199335

(51) Int. Cl. H01L 21/20

(52) U.S. Cl. 438/396

(57) ABSTRACT

A method for manufacturing a semiconductor device is disclosed, which comprises the steps of (i) forming a circuit element on a semiconductor substrate, (ii) forming a dielectric that covers the circuit element, (iii) forming a first electrode on the dielectric, (iv) forming a ferroelectric film on the first electrode, (v) forming a second electrode on the ferroelectric film, (vi) forming a hardmask on the second electrode, (vii) etching the first electrode, the ferroelectric film, and the second electrode using the hardmask as an etching mask, and (viii) removing the hardmask and redeposition that is attached after said etching to a sidewall of the ferroelectric film simultaneously.

### BACKGROUND OF THE INVENTION

Field of the Invention

The present invention relates to a method for manufacturing a semiconductor device. More specifically, the present invention relates to a method for manufacturing a semiconductor device that comprises a ferroelectric device.

Recently, a ferroelectric random access memory (FeRAM) has shown much promise as a nonvolatile semiconductor memory. The FeRAM can non-volatilely retain data, even if power supply thereto is stopped. The data readout speed of conventional nonvolatile memory, such as an electronically erasable and programmable read only memory (EEPROM) and a flash memory, is just as fast as that of dynamic random access memory (DRAM). However, the data write speed of conventional nonvolatile memory is not as fast as that of DRAM. On the other hand, the data readout speed and the data writing speed of FeRAM are just as fast as those of DRAM, compared to conventional nonvolatile memory. In addition, the number of times that data will be rewritten in FeRAM is greater than that of conventional nonvolatile memory, such as EEPROM and flash memory. Furthermore, FeRAM consumes power only during data writing or data reading. Therefore, it is possible for FeRAM to reduce power consumption compared to DRAM and have a much larger capacity than DRAM. Attention has been focused on these positive aspects of FeRAM, and thus various developments with respect to FeRAM have been achieved.

Conventional FeRAM has a capacitor and a transistor. The capacitor has a structure in which electrodes (i.e., an upper electrode and a lower electrode) are arranged on both sides of a ferroelectric film. In addition, a stacked structure has been recently used as a FeRAM capacitor structure. A reduction in the size of a memory cell can be achieved by means of a stacked structure.

When patterning a ferroelectric capacitor in a conventional stack type FeRAM, dry etching is performed with respect to an upper electrode, a ferroelectric film, and a lower electrode using the same photoresist mask in the same step. In general, residual materials are generated during the etching of an electrode and easily attach to the sidewalls of the ferroelectric capacitor. Attachment of residual materials may be hereinafter referred to as redeposition, and the attached residual materials may also be hereinafter referred to as redeposition. Attachment of the residual materials (i.e., redeposition) causes a short circuit of the sidewall and increase of leakage current of the sidewall. In some cases, chlorine gas, which has a relatively high reactivity, is used as an etching gas in order to prevent the generation and attachment of residual materials during the etching of the ferroelectric capacitor.

However, if a photoresist mask is used as an etching mask, both the upper surface and the lateral sides of the photoresist mask will easily come under the influence of the etching gas. Because of this, the gradient angle of the lateral sides will be smaller than the ideal angle of 90 degrees. As a result, the initial pattern shape is greatly changed, and the pattern is shrunk both in the vertical direction and the horizontal direction. Therefore, the pattern's gradient angle during etching tends to be less than 45 degrees, and thus miniaturization of the capacitor is prevented.

In order to solve these problems, a variety of inventions have been suggested. For example, Japan Patent Application Publication JP-A-2000-349253 discloses a method for etching an electrode comprised of platinum (Pt) and a ferroelectric film comprised of lead zirconate titanate (PZT; PbTiO₃—PbZrO₃) using a hardmask comprised of silicon dioxide (SiO₂) as an etching mask. In the etching method described in the publication, a mixed gas of chloride (Cl₂), argon (Ar), and oxygen (O₂) is used as the etching gas, which can minimize the amount of corrosion of the SiO₂ hardmask.

As described above, in the etching method described in Japan Patent Application Publication JP-A-2000-349253, a mixed gas including Cl₂ is used. Therefore, depending on conditions, it is possible to inhibit the amount of residual materials that will be generated during the etching of an electrode and a ferroelectric film to some extent. However, it is quite difficult to completely prevent residual materials from being generated. Because of this, the residual materials generated during etching must be removed.

It is possible to assume a method for performing over-etching during the dry etching of the ferroelectric capacitor as a method of removing residual materials attached to the sidewalls of a ferroelectric capacitor. However, even this method has a drawback, in that the effective area of a capacitor will be reduced.

In view of the above, it will be apparent to those skilled in the art from this disclosure that there exists a need for an improved method for manufacturing a semiconductor device. This invention addresses this need in the art as well as other needs, which will become apparent to those skilled in the art from this disclosure.

### SUMMARY OF THE INVENTION

It is therefore an object of the present invention is to provide a method for manufacturing a ferroelectric device, which can remove residual materials attached to the sidewalls of a ferroelectric capacitor comprised of a lower electrode, a ferroelectric film, and an upper electrode in an etching step without reducing the effective area of the ferroelectric capacitor.

In accordance with the present invention, a method for manufacturing a semiconductor device is comprised of the steps of (i) forming a circuit element on a semiconductor substrate, (ii) forming a dielectric that covers the circuit element, (iii) forming a first electrode on the dielectric, (iv) forming a ferroelectric film on the first electrode, (v) forming a second electrode on the ferroelectric film, (vi) forming a hardmask on the second electrode, (vii) etching the first electrode, the ferroelectric film, and the second electrode using the hardmask as an etching mask, and (viii) simultaneously removing the hardmask that remains after the etching of the first electrode, the ferroelectric film, and the second electrode, and redeposition that attaches to the sidewalls of the ferroelectric film during etching.

According to the present invention, the removal of the remaining hardmask that remains after the etching of the first electrode, the ferroelectric film, and the second electrode, and the removal of redeposition attached to the sidewalls of the ferroelectric film during etching, are simultaneously performed. Because of this, it is possible to remove deposition attached to the sidewalls of the ferroelectric film without reducing the effective area of a ferroelectric capacitor structure comprised of the first electrode, the ferroelectric film, and the second electrode, compared to a situation in which redeposition attached to the sidewalls of the ferroelectric film is removed by performing over-etching.

These and other objects, features, aspects and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIGS. 1A to 1D are cross-section diagrams showing a portion of a manufacturing process of a semiconductor device in accordance with one embodiment of the present invention;

FIGS. 2A to 2C are cross-section diagrams showing a portion of a manufacturing process of a semiconductor device in accordance with one embodiment of the present invention;

FIGS. 3A to 3C are cross-section diagrams showing a portion of a manufacturing process of a semiconductor device in accordance with one embodiment of the present invention;

FIGS. 4A to 4C are cross-section diagrams showing a portion of a manufacturing process of a semiconductor device in accordance with one embodiment of the present invention;

FIGS. 5A to 5C are cross-section diagrams showing a portion of a manufacturing process of a semiconductor device in accordance with one embodiment of the present invention; and

FIG. 6 is a cross-section diagram showing a portion of a manufacturing process of a semiconductor device in accordance with one embodiment of the present invention.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

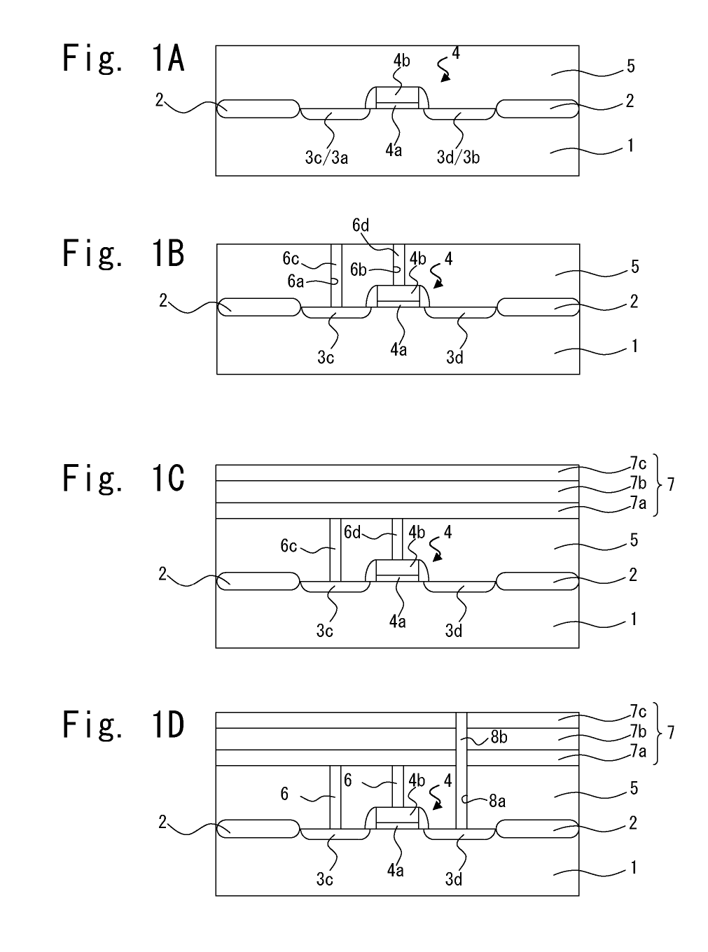

Referring now to FIGS. 1A to 1D, 2A to 2C, 3A to 3C, 4A to 4C, 5A to 5C, and 6, a method for manufacturing a semiconductor device that comprises a ferroelectric capacitor in accordance with one embodiment of the present invention will be hereinafter explained in detail. These figures are cross-section diagrams showing a manufacturing process of the semiconductor device in accordance with one embodiment of the present invention. Formation of laminated film and hardmask

As shown in FIG. 1A, an isolation region 2 using the local oxidation of silicon (LOCOS) technique and the like, and active regions 3a and 3b, are formed on a semiconductor substrate 1 with a heretofore known Si semiconductor process. Then, material for forming a gate dielectric and material for forming a gate electrode are sequentially laminated on the semiconductor substrate 1, and patterning of these materials is performed. Thus, a gate dielectric 4a and a gate electrode 4b are formed. Furthermore, a sidewall 4c is formed. Here, the gate electrode 4b is comprised of p-doped polycrystal silicon (p-Si) or a polyside (WSiₓ/p-Si) structure, for instance.

Next, impurity ions are implanted into the active regions 3a and 3b. The implanted impurity ions are then diffused, and source/drain regions 3c and 3d are formed. Thus, a transistor 4 is formed. Next, an inter-layer dielectric 5 comprised of an oxide film such as SiO₂ is formed above the semiconductor substrate 1 with the chemical vapor deposition (CVD) method, for instance. More specifically, the inter-layer dielectric 5 is formed to cover the transistor 4. Then, the inter-layer dielectric 5 is planarized with the chemical mechanical polishing (CMP) method, for instance. Here, the film thickness of the inter-layer dielectric 5 is set to be approximately 500 nm.

Next, as shown in FIG. 1B, openings 6a and 6b are formed in the inter-layer dielectric 5 with photolithoetching. Thus, the source/drain region 3c and the gate electrode 4b are exposed through the openings 6a and 6b, respectively. In addition, tungsten (W) is implanted into the openings 6a and 6b, and an etch-back is performed with respect to the implanted tungsten. Thus, contact plugs 6c and 6d are formed. Here, as shown in FIG. 1B, the contact plug 6c is electrically connected to the source/drain region 3c. On the other hand, the contact plug 6d is electrically connected to the gate electrode 4b.

Next, as shown in FIG. 1C, an oxide film 7a, a nitride film 7b, and an oxide film 7c are sequentially deposited on the inter-layer dielectric 5 with the CVD method. Thus, a three-layer oxygen diffusion barrier layer 7 is formed. The oxygen diffusion barrier layer 7 is formed to protect the contact plugs 6c and 6d from oxygen in an annealing step performed in an oxygen atmosphere. Here, the oxide film 7a is comprised of SiO₂ and the thickness thereof is set to be 100 nm. The nitride film 7b is comprised of silicon nitride (Si₃N₄) and the thickness thereof is set to be 120 nm. The oxide film 7c is comprised of SiO₂ and the thickness thereof is set to be 100 nm.

Next, as shown in FIG. 1D, an opening 8a is formed which penetrates the oxygen diffusion barrier layer 7 and the inter-layer dielectric 5. Then, metal such as tungsten (W) is implanted into the opening 8a with the CVD method, and thus a contact plug 8b is formed. Here, the contact plug 8b is formed to be electrically connected to the source/drain region 3.

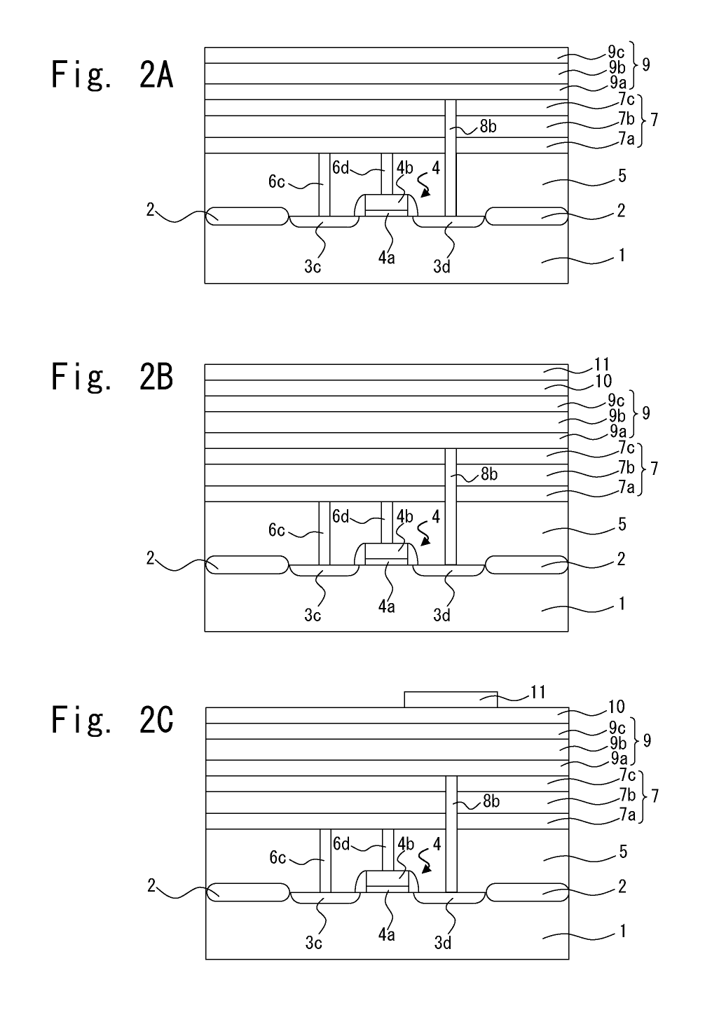

Next, as shown in FIG. 2A, a laminated structure film 9 of a ferroelectric capacitor, which is comprised of a lower electrode 9a, a ferroelectric film 9b, and an upper electrode 9c, is formed on the oxygen diffusion barrier layer 7. More specifically, first, the lower electrode 9a is formed on the oxygen diffusion barrier layer 7. Here, an oxidation-resistant metal or a conductive metal oxide is used as the lower electrode 9a. For example, the lower electrode 9a is formed by sequentially depositing an iridium (Ir) layer, an iridium dioxide (IrO₂) layer, and a Pt layer with the sputtering method or the CVD method. Here, film thicknesses of the Ir layer, the IrO₂ layer, and the Pt layer are all set to be 100 nm.

Note that the lower electrode 9a may be comprised of a single layer film of Pt, Ir, ruthenium (Ru), iridium oxide (IrOₓ), ruthernium oxide (RuOₓ), or RuSrOₓ, or comprised of a multilayer film (i.e., a laminated film) formed by a combination of at least two of these materials. Note that an adhesive layer may be deposited between the lower electrode 9a and the contact plug 8b. Here, the adhesive layer (not shown in the figure) may be comprised of an aluminum titanium nitride (AlTiN) film, a titanium nitride (TiN) film, and the like, and the film thickness thereof may be set to be 50 nm.

Then, the ferroelectric film 9b is formed on the lower electrode 9a. Here, strontium bismuth tantalate (SBT; SrBi₂Ta₂O₉) is used as the ferroelectric film 9b, and the film thickness thereof is set to be 120 nm. In addition, the ferroelectric film 9b is formed with the sputtering method or the CVD method. Note that the ferroelectric film 9b may be formed with the sol-gel method. In addition, an inorganic ferroelectric film comprised of PZT, lead lanthanum zirconate titanate (PLZT), strontium bismuth tantalite niobate (SBTN), bismuth lanthanum titanate (BLT), and the like may be formed as the ferroelectric film 9b instead of using SBT.

Next, the ferroelectric film 9b is crystallized by conducting a thermal treatment (hereinafter called crystallization thermal treatment). More specifically, the thermal treatment is performed in a high-temperature oxygen atmosphere at 800 degrees Celsius for one minute, for example. Then, the upper electrode 9c is formed on the ferroelectric film 9b. Here, the upper electrode 9c is comprised of Pt, and the film thickness thereof is set to be 150 nm. In addition, the upper electrode 9c is formed with the sputtering method or the CVD method. Note that the upper electrode 9c may be comprised of a single layer film comprised of Ir, Ru, IrOₓ, RuOₓ, RuSrOₓ, and the like, or a multilayer film (i.e., a laminated film) formed by a combination of at least two of these materials.

Next, as shown in FIG. 2B, a hardmask 10 is formed on the upper electrode 9c with the CVD method. The hardmask 10 is used as an etching mask in a later step. The hardmask 10 is an amorphous dielectric comprised of a single layer strontium titanate oxide (STO; SrTa₂O₆) film.

Note that STO has a very strong resistance to dry etching, but has a weak resistance to wet etching, in which a mixture including nitric acid and fluorinated acid is used with glacial acetic acid functioning as a buffer. The film thickness of STO in accordance with the present embodiment is set to be 440 nm. However, this thickness can be arbitrarily changed depending on the taper that is necessary for a capacitor.

Next, an oxide film 11 is formed on the hardmask 10 with the CVD method. The oxide film 11 is comprised of plasma tetraethoxysilane (a p-TEOS; Si(OC₂H₅)₄) film, and the film thickness thereof is set to be 700 nm. The oxide film 11 has a strong resistance to wet etching. As described below, the oxide film 11 is used as an etching mask in the etching of the hardmask 10.

Etching of Hardmask

As shown in FIG. 2C, patterning is performed with respect to the oxide film 11 with the lithography and the dry etching. Here, the etching conditions are set as follows. That is, gas flow rates of tetrafluoromethane (CF₄), carbon oxide (CO), and Ar are set to be 0.07, 0.25, and 1 sccm, respectively. The gas pressure is set to be 0.067 Pa. The RF power is set to be 1500 W. The substrate temperature is set to be 40 degrees Celsius.

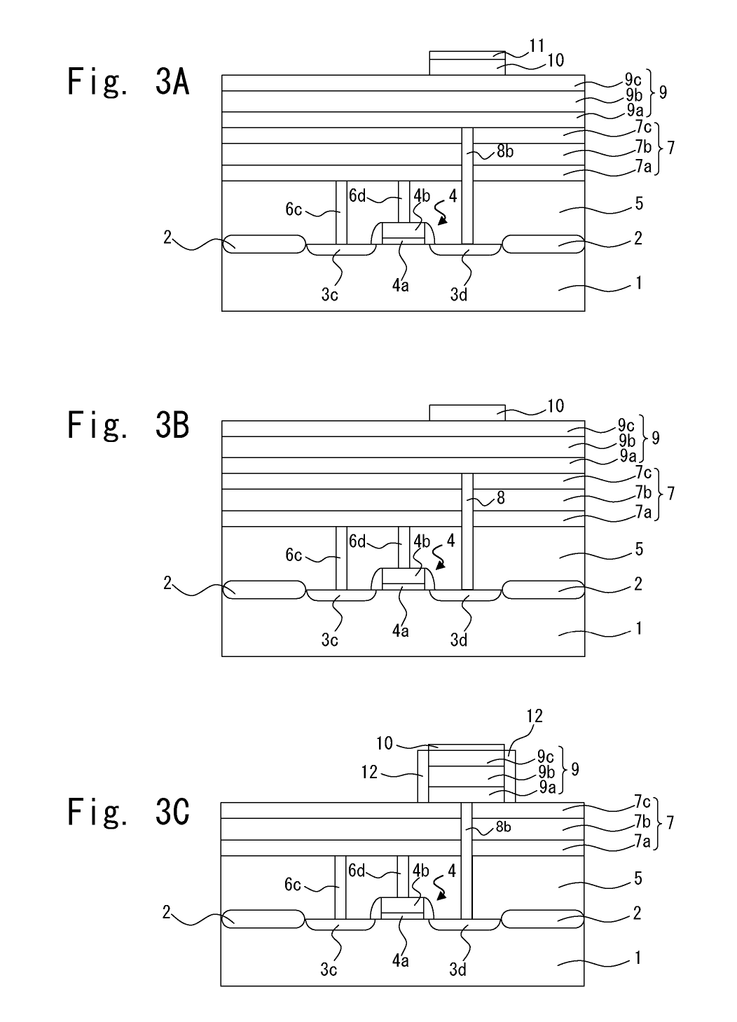

Next, as shown in FIG. 3A, wet etching is performed with respect to the hardmask 10 using the oxide film 11 as an etching mask. As described above, the oxide film 11 has strong resistance to wet etching, in which a mixture including nitric acid and fluorinated acid is used with glacial acetic acid functioning as a buffer. On the other hand, the hardmask 10 has weak resistance to wet etching. In addition, the etching selectivity of the oxide film 11 with respect to STO comprising the hardmask 10 is sufficiently large. Therefore, it is possible to selectively perform only the etching of the hardmask 10. Here, the wet etching conditions are set as follows. That is, the concentrations of nitric acid and fluorinated acid are 59 wt % and 0.5 wt %, respectively. The temperature is set to be room temperature. The etching speed is set to be 100 nm per minute.

Next, as shown in FIG. 3B, the oxide film 11 is removed by dry etching. Here, the etching conditions are set as follows. That is, the gas flow rates of CF₄, CO, and Ar are set to be 0.07, 0.25, and 1 sccm, respectively. The gas pressure is set to be 0.067 Pa. The RF power is set to be 1500 W. The substrate temperature is set to be 40 degrees Celsius. Etching of laminated film and adhesion layer

As shown in FIG. 3C, the dry etching is performed with respect to the upper electrode 9c, the ferroelectric film 9b, and the lower electrode 9a, correctively, using the hardmask 10 as an etching mask. Here, the dry etching conditions are set as follows. That is, the gas flow rates of Cl₂ and Ar are set to be 10 and 10 sccm, respectively. The gas pressure is set to be 0.667 Pa. The RF power is set to be 550 W. The substrate temperature is set to be 80 degrees Celsius.

The etching selectivity of the STO hardmask 10 with respect to the upper electrode 9c, the ferroelectric film 9b, and the lower electrode 9a is large. Therefore, it is possible to form a good laminated structure film 9 of the ferroelectric capacitor using a single layer STO film. After the etching of the laminated structure film 9, redeposition 12 will have been attached to the sidewall of the laminated structure film 9. The redeposition 12 is composed of chemical compounds of Ir or Pt, both of which comprise the lower electrode 9a. For example, if the upper electrode 9c and the lower electrode 9a become electrically connected to each other due to the attachment of the redeposition 12, there is a possibility that a leakage current will be generated.

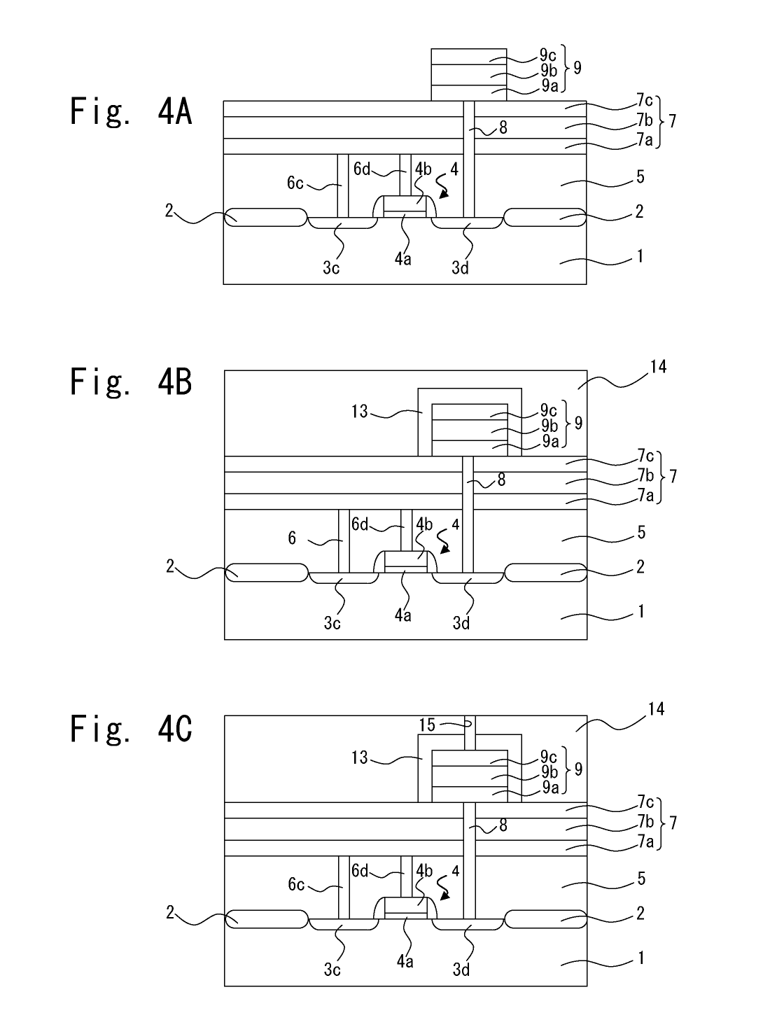

Next, as shown in FIG. 4A, the remaining hardmask 10 on the upper electrode 9c is removed by performing wet etching, in which a mixture including nitric acid and fluorinated acid is used with glacial acetic acid functioning as a buffer. Here, the wet etching conditions are set as follows. That is, the concentrations of nitric acid and fluorinated acid are set to be 59 wt % and 0.5 wt %, respectively. The temperature is set to be room temperature. The etching speed is set to be 100 nm per minute.

The chemical compounds of Ir or Pt can be removed using the mixture including nitric acid and fluorinated acid. Therefore, when wet etching is performed to remove the hardmask 10, the redeposition 12 composed of chemical compounds of Ir or Pt, and attached to the sidewall of the laminated structure film 9, can be simultaneously removed.

Note that a damage layer (not shown in the figure) is formed on the edge portion of the sidewalls of the ferroelectric film 9b, that is, the sidewalls of the ferroelectric film 9b covered by the redeposition 12 if exposed to a high-temperature oxygen-deficient atmosphere. Here, the damage layer is formed when the crystal structure of the ferroelectric film 9b is affected and altered, and this may have adverse impact on the polarization properties of the ferroelectrics. In the above described wet etching, the damage layer also can be removed. Steps after etching of laminated structure film

As shown in FIG. 4B, a first hydrogen barrier film 13 is formed on the laminated film 9 with the CVD method or the sputtering method. The first hydrogen barrier film 13 is comprised of titanium aluminum (TiAl) alloy, titanium aluminum oxide (TiAlOx), aluminum oxide (Al₂O₃), or the like. Then, the first hydrogen barrier film 13 is patterned into a desired shape with photolithoetching, and a second inter-layer dielectric 14 is formed with the CVD method. Here, the second inter-layer dielectric 14 is comprised of SiO₂, and the thickness thereof is set to be 850 nm. Here, the hydrogen barrier film 13 is formed to prevent hydrogen from entering the ferroelectric capacitor when a reducing agent is used in a later step of forming a contact plug.

Next, as shown in FIG. 4C, an opening 15 is formed by means of photolithoetching which penetrates the second inter-layer dielectric 14 and the first hydrogen barrier film 13. Thus, the upper electrode 9c is exposed through the opening 15.

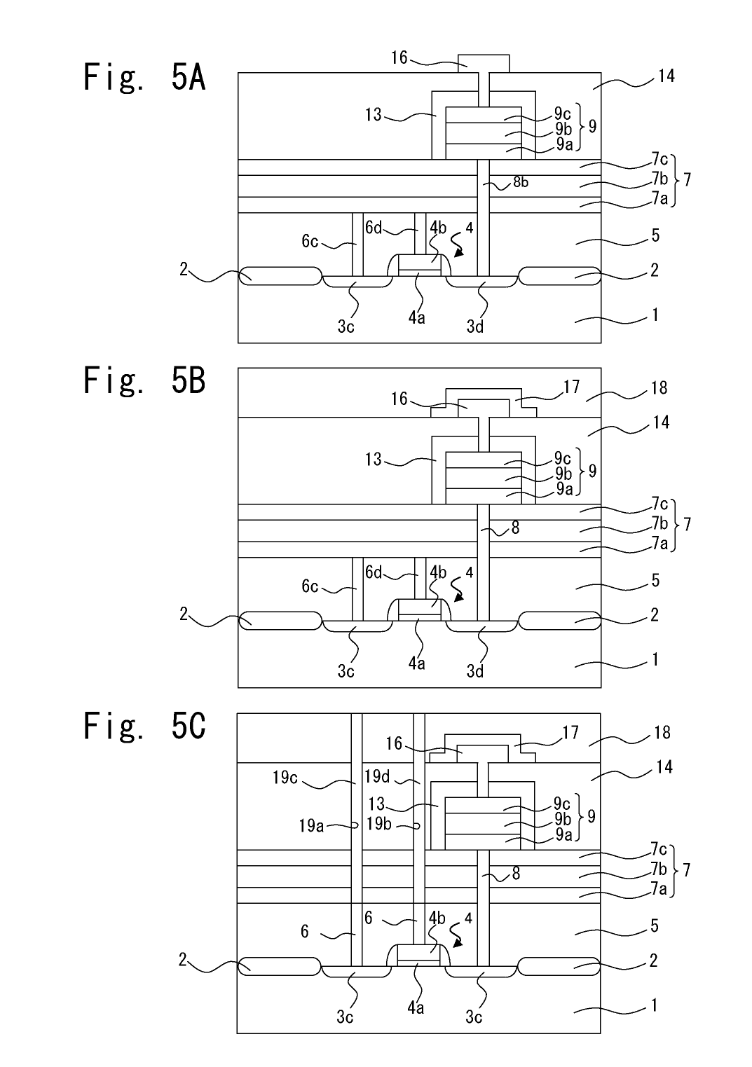

Next, as shown in FIG. 5A, a single layer of TiN or Al alloy, or a multilayer (i.e., a laminated layer) including TiN and Al alloy is implanted into the opening 15. Then, patterning is performed with respect to the single layer or the multilayer, and thus a first metal wiring 16 is formed. Here, if the first metal wiring 16 is comprised of the multilayer, TiN, Ti, Al, Ti, TiN may be sequentially laminated, for instance. Accordingly, the first metal wiring 16 is electrically connected to the upper electrode 9c.

Next, as shown in FIG. 5B, a second hydrogen barrier layer 17 is formed on the first metal wiring 16 with the CVD method or the sputtering method. The second hydrogen barrier film 17 is comprised of TiAl alloy, TiAlOₓ, Al₂O₃, and the like. Then, the second hydrogen barrier film 17 is patterned into an intended shape. A third inter-layer dielectric 18 is formed to cover the second hydrogen barrier film 17 with the CVD method. Here, the third inter-layer dielectric 18 is comprised of SiO₂, and the film thickness thereof is set to be 800 nm. Here, the second hydrogen barrier film 17 is formed to prevent hydrogen from entering the ferroelectric capacitor when a reducing agent is used in a later step of forming a contact plug.

As shown in FIG. 5C, openings 19a and 19b are formed by means of photolithoetching. The openings 19a and 19b penetrate the third inter-layer dielectric 18, the second inter-layer dielectric 14, and the oxygen diffusion barrier layer 7, and expose the contact plugs 6c and 6d, respectively. Then, metal such as tungsten (W) is implanted in the openings 19a and 19b with the CVD method, for instance. Thus, contact plugs 19c and 19d are formed, respectively. Here, the contact plug 19c is electrically connected to the source/drain region 3c through the contact plug 6c. On the other hand, the contact plug 19d is electrically connected to the gate electrode 4b comprising the transistor 4 through the contact plug 6d. Then, openings (not shown in the figure) are formed in the third inter-layer dielectric 18, and the second hydrogen barrier film 17 is exposed through the openings.

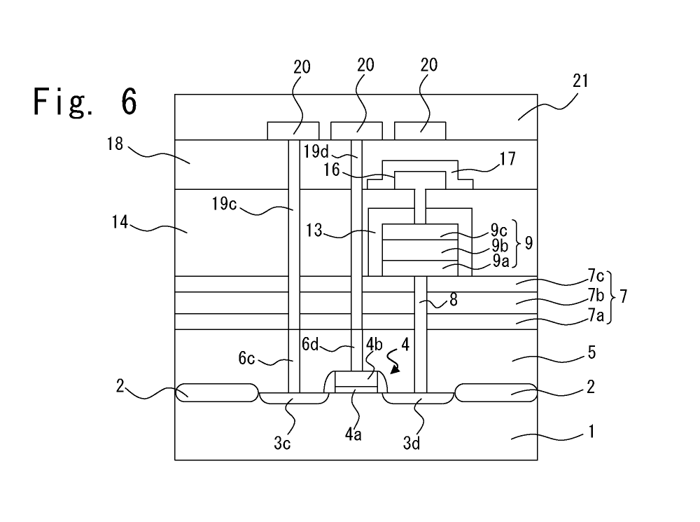

Next, as shown in FIG. 6, a metal layer is formed on the third inter-layer dielectric 18 with the sputtering method. Then, photolithoetching is performed with respect to the metal layer, and thus a second metal wiring layer 20 is formed. Here, the second metal wiring layer 20 is comprised of a single layer of TiN or Al alloy, or a multilayer (i.e., a laminated layer) including TiN and Al alloy. If the second metal wiring layer 20 is comprised of the laminated layer, TiN, Ti, Al, Ti, and TiN are sequentially laminated.

The second metal wiring layer 20 is electrically connected to the source/drain region 3c through the contact plugs 19c and 6c. In addition, the second metal wiring layer 20 is electrically connected to the gate electrode 4b comprising the transistor 4 through the contact plugs 19d and 6d.

When the metal layer is formed on the third inter-layer dielectric 18, the metal layer is also implanted in the above described openings (not shown in the figure) formed in the third inter-layer dielectric 18. Thus, the second metal wiring layer 20 is formed and electrically connected to the second hydrogen barrier film 17.

Next, a passivation film 21 is formed to cover the second metal wiring layer 20 with the CVD method. Here, the passivation film 21 is comprised of Si₃N₄, and the film thickness thereof is set to be 200 nm.

According to the present invention, when the remaining hardmask 10 is removed, which is left after the etching of the laminated structure film 9 of the ferroelectric capacitor comprised of the upper electrode 9c, the ferroelectric film 9b, and the lower electrode 9, the redeposition 12 attached to the sidewall of the laminated film 9 will be simultaneously removed. Therefore, compared to a situation in which the redeposition is removed by performing over-etching when the laminated structure film 9 is etched, it is possible to remove the redeposition 12 without reducing the effective area of the laminated structure film 9.

In addition, according to the present embodiment of the present invention, when the remaining hardmask 10 that is left after the etching of the laminated structure film 9 is removed, the damage layer formed on the sidewall of the ferroelectric film 9b can be removed in addition to the removal of the redeposition 12.

In addition, as described above, the removal of the remaining hardmask 10 that is left after the etching of the laminated structure film 9 makes it possible to simultaneously perform the removal of the redeposition 12 and the removal of the damage layer formed on the sidewalls of the ferroelectric film 9. Therefore, the manufacturing process of the semiconductor device can be simplified, and thus manufacturing costs can be reduced.

In addition, according to the present embodiment of the present invention, p-TEOS that has strong resistance to wet etching is used as the oxide film 11 functioning as an etching mask of the hardmask 10, and STO that has strong resistance to dry etching and has weak resistance to wet etching is used as the hardmask 10. Because of this, it is possible to prevent the hardmask 10 from being etched when wet etching is performed with respect to the hardmask 10, and then the remaining oxide film 11 is removed by dry etching after wet etching is performed. Accordingly, it is possible to keep the hardmask 10 in a good pattern shape.

Furthermore, as described above, dry etching can be performed with respect to the laminated structure film 9 using the hardmask 10 that has a good pattern shape as an etching mask. Therefore, it is possible to perform etching with respect to the laminated structure film 9 at an ideal angle that is approximately perpendicular to the horizontal direction.

Moreover, according to the present embodiment of the present invention, dry etching is performed with respect to the laminated structure film 9 collectively by using the single layer hardmask 10 as an etching mask. Therefore, compared to a situation in which a multilayer hardmask is used as an etching mask and dry etching is performed with respect to the laminated film 9, the etching process can be simplified and manufacturing costs can be reduced.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

This application claims priority to Japanese Patent Application No. 2005-199335. The entire disclosure of Japanese Patent Application No. 2005-199335 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A method for manufacturing a semiconductor device, comprising the steps of:
forming a circuit element on a semiconductor substrate;
forming a dielectric that covers the circuit element;
forming a first electrode on the dielectric;
forming a ferroelectric film on the first electrode;
forming a second electrode on the ferroelectric film;
forming a hardmask on the second electrode;
etching the first electrode, the ferroelectric film, and the second electrode using the hardmask as an etching mask; and
simultaneously removing the hardmask that remains after the etching of the first electrode, the ferroelectric film, and the second electrode, and redeposition that attaches to a sidewall of the ferroelectric film in the etching.

2. The method for manufacturing a semiconductor device according to claim 1, wherein a damage layer formed on the sidewall of the ferroelectric film during the etching is also removed simultaneously with the removal of the hardmask and the redeposition.

3. The method for manufacturing a semiconductor device according to claim 1, wherein the hardmask is comprised of strontium titanate oxide (STO; SrTa₂O₆).

4. The method for manufacturing a semiconductor device according to claim 3, wherein the removal of the hardmask is performed with a wet etching.

5. The method for manufacturing a semiconductor device according to claim 4, wherein solution used for the wet etching is a mixture comprising nitric acid and fluorinated acid.

6. The method for manufacturing a semiconductor device according to claim 3, further comprising the steps of:
forming an oxide film on the hardmask; and
etching the hardmask using the oxide film as an etching mask prior to the etching of the second electrode, the ferroelectric film, and the first electrode.

7. The method for manufacturing a semiconductor device according to claim 6, wherein the etching of the hardmask is performed with a wet etching.

8. The method for manufacturing a semiconductor device according to claim 1, wherein the first electrode is comprised of a single layer film comprised of one element or compound selected from the group consisting of platinum (Pt), iridium (Ir), ruthenium (Ru), iridium oxide (IrOₓ), ruthenium oxide (RuOₓ), and RuSrOₓ.

9. The method for manufacturing a semiconductor device according to claim 1, wherein the first electrode is comprised of a multilayer film comprised of at least two elements, compounds, or a combination of an element and a compound selected from the group consisting of Pt, Ir, Ru, IrOₓ, RuOₓ, and RuSrOₓ.

10. The method for manufacturing a semiconductor device according to claim 1, wherein the second electrode is comprised of a single layer film comprised of one element or compound selected from the group consisting of Pt, Ir, Ru, IrOₓ, RuOₓ, and RuSrOₓ.

11. The method for manufacturing a semiconductor device according to claim 1, wherein the second electrode is comprised of a multilayer film comprised of at least two elements, compounds, or a combination of an element and a compound selected from the group consisting of Pt, Ir, Ru, IrOₓ, RuOₓ, and RuSrOₓ.

12. The method for manufacturing a semiconductor device according to claim 1, wherein the ferroelectric film is comprised of one compound selected from the group consisting of strontium bismuth tantalite (SBT), lead zirconate titanate (PZT), lead lanthanum zirconate titanate (PLZT), strontium bismuth tantalite niobate (SBTN), and bismuth lanthanum titanate (BLT).
